(19) United States
(12) Patent Application Publication
(10) Pub. No.: US 2007/0121293 A1
(43) Pub. Date: May 31, 2007

(54) Cooling module holder

(75) Inventors: Alex Hong, Kaohsiung City (TW); Miyahara Masaharu, Kaohsiung City (TW)

Correspondence Address: BACON & THOMAS, PLLC, 625 SLATERS LANE, FOURTH FLOOR, ALEXANDRIA, VA, 22314, US

(73) Assignee: Sunonwealth Electric Machine Industry Co., Ltd., Kaohsiung City (TW)

(21) Appl. No.: 11/318,610

(22) Filed: Dec. 28, 2005

(30) Foreign Application Priority Data
Nov. 29, 2005 (TW) 094141799

(51) Int. Cl. H05K 7/20

(52) U.S. Cl. 361/697

(57) ABSTRACT

An improved cooling module holder has a main body with two sides, a cooling fan and a heat sink disposed on the both sides respectively in formation of a cooling module. The ventilation hole corresponding to the cooling fan is disposed on the main body. At least one still leaf extends inwardly from the inner rim of the ventilation hole. When the cooling fan drives air flow to pass through those leaves, the still leave enables to lower the noise resulting from the pressure resonance and eliminating the unnecessary pressure loss caused by turbulence. Another wind pressure is formed along the tangent direction of the still leaf capable of avoiding the loss from the wind pressure. Meanwhile, the cooling performance of the cooling fan is enhanced by the wind pressure, achieving faster and more efficient cooling effect and improving the overheated issue at the lower half of the heat sink.

### FIELD OF THE INVENTION

The invention relates to an improved holder of a cooling module disposed at the CPU of electronic products, providing a practical structure with multiple effects in boosting pressure, guiding air flow, lowering noise, enhancing cooling performance.

### BACKGROUND OF THE INVENTION

As shown in FIG. 1, a cooling module disposed at a CPU of a cooling module includes a heat sink 10, a holder 20 and a cooling fan 30. The heat sink 10 directly contacts with a heating element to absorb the heat thereof. The cooling fan 30 is fastened by the holder 20 and disposed atop the heat sink 10 to dissipate the heat.

The heat sink 10 includes a central heat conductor 11 and a plurality of cooling fins 12 extending outwardly from the periphery of the central heat conductor 11.

The holder 20 has a main body 21 disposed a fan-positioning slot for assembling and fixing the cooling fan 30. The main body is also disposed a ventilation hole 23 corresponding to the cooling fan 30. A plurality of positioning parts 24 extend from the inner rim of the ventilation hole 23 to be engaged with the heat sink 10 by screws in formation of a cooling module. In addition, a plurality of feet 25 extend downwardly from the boundary of the main body 21 to be assembled with the cooling module on a specified position atop the heating element.

As a result, by directly contacting with and absorbing the heat from the heat sink and diffusing heat upwardly to the surrounding cooling fins 12, the cooling fan 30 is used to simultaneously drive the air flow for quickly dissipating the heat.

However, when the heat absorbed by the heat sink 10 rises up from the bottom and gradually diffuses to the ambient environment, an anisothermal phenomenon results from the higher temperatures of the central heat conductor 11 and the lower half portion of the cooling fins as well as the lower temperature of the upper half portion. Under the premise changing no current specification and the surrounding configuration, should the issue of the anisothermal cooling fins be solved, the cooling performance can be enhanced only by increasing the wind volume and the wind pressure of the cooling fan 30 so as to further provide the faster and more efficient heat-dissipating effect against the overheated issue of the central heat conductor 11 and the lower half portion of the cooling fins 12.

### SUMMARY OF THE INVENTION

As shown in FIG. 1, the cooling module disposed for the CPU of the electronic product contains a heat sink 10, a holder 20 and a cooling fan 30. The heat sink 10 directly contacts with a heating element to absorb the heat thereof. The cooling fan 30 is fastened atop the heat sink 10 using the holder 20 to dissipate the heat.

The heat sink 10 contains a central heat conductor 11 and a plurality of cooling fins extending outwardly from the periphery of the central heat conductor 11.

The holder 20 has a main body 21. The main body 21 is disposed a fan-positioning slot 22 on the top side, allowing the cooling fan 30 to be assembled and fixed. The main body 21 is also disposed a ventilation hole 23 corresponding to the cooling fan 30. A plurality of positioning parts 24 extending from the inner rim of the ventilation hole 23 can be engaged with the heat sink 10 by screws in formation of a cooling module. In addition, a plurality of feet 25 extend downwardly from the comers of the main body 21 to assemble the cooling module on a specified position atop the heating element.

Consequently, by directly contacting with and absorbing the heat from the heat sink and diffusing heat upwardly to the surrounding cooling fins 12, the cooling fan 30 is used to simultaneously drive the air flow for quickly dissipating the heat.

However, when the heat absorbed by the heat sink 10 rises up from the bottom and gradually diffuses to the ambient environment, an anisothermal phenomenon results from the higher temperatures of the central heat conductor 11 and the lower half portion of the cooling fins as well as the lower temperature of the upper half portion. Under the premise changing no current specification and the surrounding configuration, should the issue of the anisothermal cooling fins be solved, the cooling performance can be enhanced only by increasing the wind volume and the wind pressure of the cooling fan 30 so as to further provide the faster and more efficient heat-dissipating effect against the overheated issue of the central heat conductor 11 and the lower half portion of the cooling fins 12.

### BRIEF DESCRIPTION OF THE DRAWINGS

FIG. 1 is an exploded view showing the conventional structure of the cooling module structure;

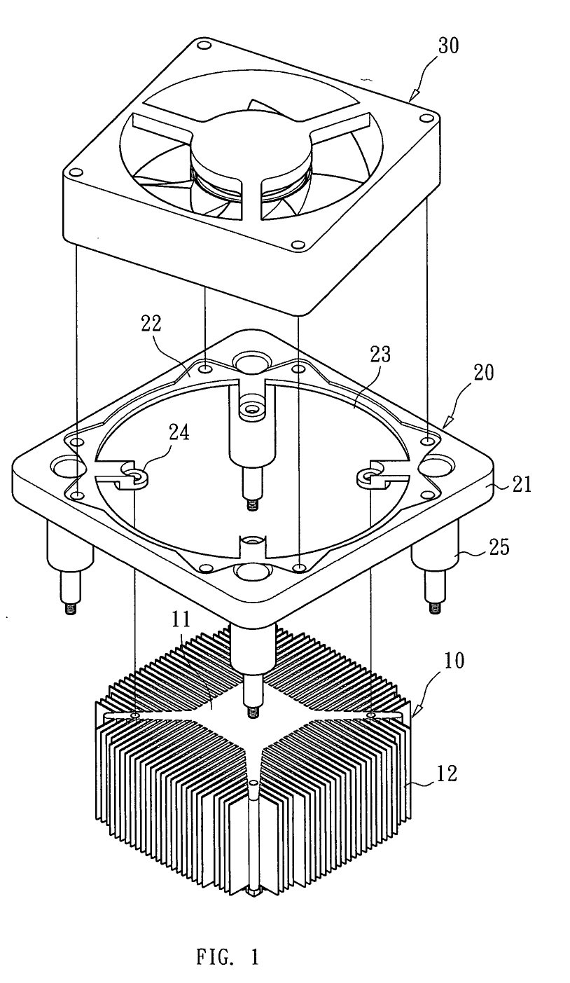

FIG. 2 is an exploded view showing the first preferred embodiment of the present invention;

FIG. 3 is a cross-sectional view showing the first preferred embodiment of the present invention;

FIG. 4 is a plane schematic view showing the first preferred embodiment;

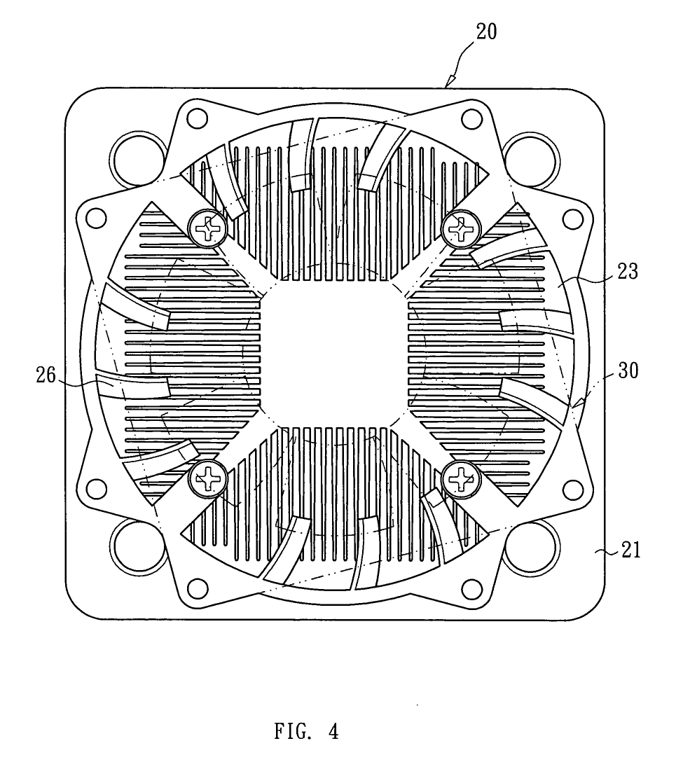

FIG. 5 is an exploded view showing the second preferred embodiment of the present invention;

FIG. 6 is a cross-sectional view showing the second preferred embodiment of the present invention; and

FIG. 7 is a plane schematic view showing the second preferred embodiment of the present invention.

### DETAILED DESCRIPTION OF THE PREFERRED EMBODIMENT

The invention relates to an improved cooling module holder including a heat sink 10, a holder 20 and a cooling fan 30. The heat sink 10 directly contacts with a heating element to absorb the heat thereof. The cooling fan is fastened and disposed atop the heat sink 10 with the holder 20 so as to dissipate the heat. There are two preferred embodiments illustrated below as examples.

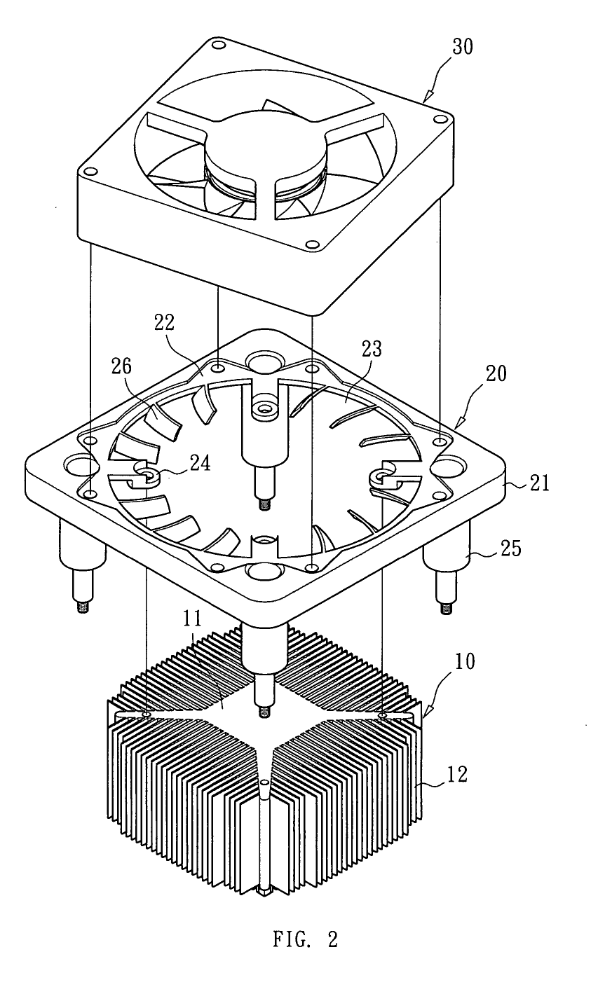

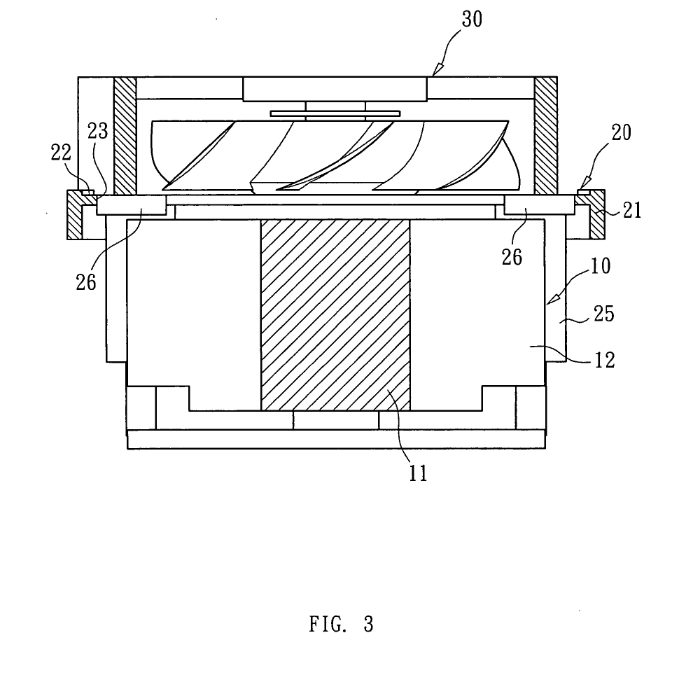

FIG. 2 and FIG. 3 illustrate the first preferred embodiment of the present invention. The heat sink 10 contains 1 central heat conductor 11 and a plurality of cooling fins 12 extending outwardly from the periphery of the central heat conductor 11.

The holder 20 has a main body 21 disposed a fan-positioning slot 22 on the top side for assembling and fixing the cooling fan 30 and a ventilation hole 23 corresponding to the cooling fan 30. A plurality of positioning parts 24 extend from the inner rim of the ventilation hole 23 are engaged with the heat sink 10 by screws in formation of a cooling module. In addition, a plurality of feet 25 extend downwardly from the boundary of the main body 21 to be assembled with the cooling module on a specified position atop the heating element.

Besides, a plurality of still blades 26 extending inwardly from the inner rim of the ventilation hole of the holder 20. The still blades are in form of a plate having an angle of tilt or a pattern similar to the blade of the cooling fan 30.

Together with the illustration of FIG. 2, 3 and 4, when the cooling fan 30 drives an air flow to pass through those still blades 26, the still blades 26 function to guide the air flow so as to alleviate the noise arising from the resonance done by the pressure. Furthermore, a wind pressure is formed along the tangent direction of the still blade 26, possibly avoiding the wind pressure loss caused by the turbulence of the air flow on the one hand and enhancing the cooling performance of the cooling fan 30 by means of the wind pressure on the other hand. The heat absorbed by the heat sink 10 can be swiftly dissipated to attain faster and more efficient cooling effect.

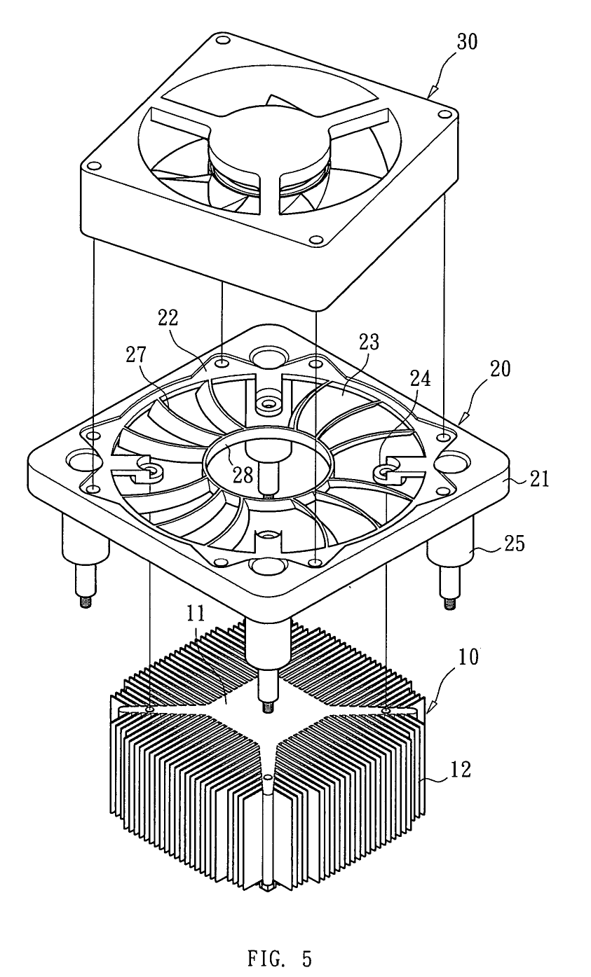

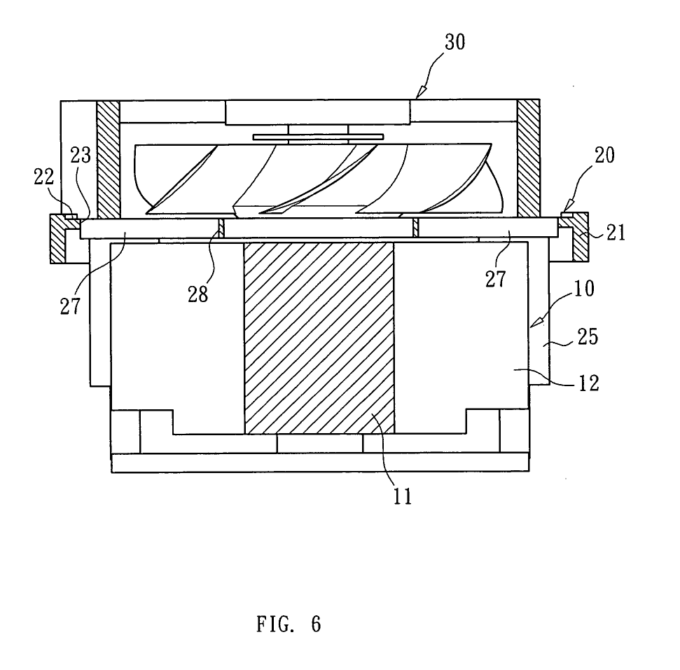

FIG. 5 and FIG. 6 illustrate the second preferred embodiment of the present invention. The inner rim of the ventilation hole 23 of the holder 20 is disposed a plurality of still blades 27 extending inwardly. Those still blades 27 are in form of plate having an angle of tilt or the pattern similar to the blades 30 of the cooling fan 30. The still blades 27 of the second preferred embodiment are longer than the still blades of the first embodiment, and the inner side of each still blade 27 is connected with a fixing ring 28.

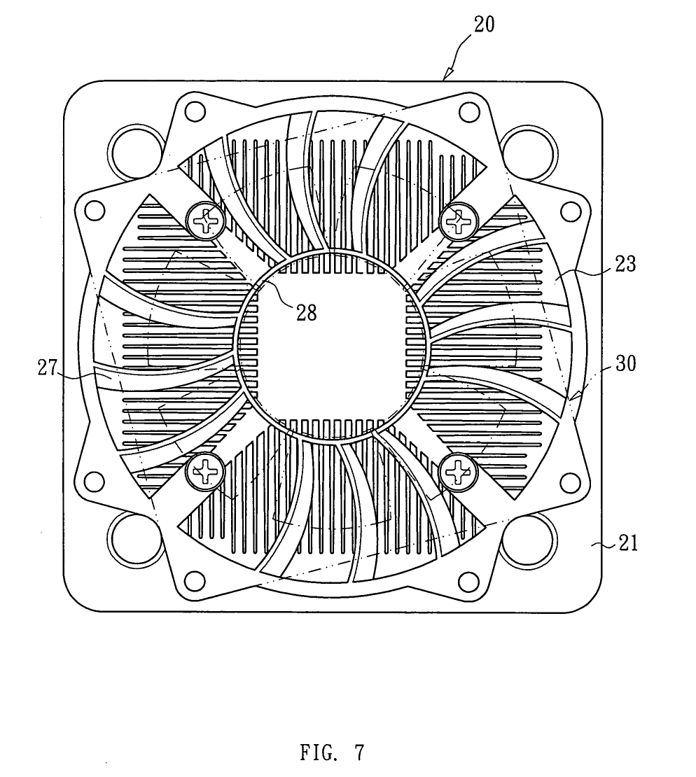

Together with the reference to FIGS. 5, 6 and 7, when the cooling fan drives the air flow to pass through those blades 27, the still blades 27 function similarly to guide the air flow so as to alleviate the noise arising from the resonance done by the pressure. The design of the fixing ring 28 provides the sufficient strength of each still blade 27 so as to prevent the still blade from generating resonance or vibration due to the wind pressure effect. Moreover, a gust of wind pressure is formed additionally along the tangent direction. On the one hand, the loss of wind pressure resulting from the turbulence of air flow is avoided, and on the other hand, the cooling performance of the cooling fan 30 is improved by means of the wind pressure so that the heat absorbed by the heat sink 10 can be swiftly dissipated to attain faster and more efficient cooling effect.

In sum, the present invention utilizes a plurality of still blades extending from the inner rim of the ventilation hole of the holder to firstly guide the air flow for reducing the noise generated by the resonance done by the pressure and to secondly form a gust of wind pressure, avoiding the loss of wind pressure generated by the turbulence of air flow. Moreover, the entire cooling performance is enhanced by means of the wind pressure, achieving faster and more efficient cooling effect. Therefore, the present invention not only has a novelty and a progressiveness, but also has an industry utility.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims, which are to be accorded with the broadest interpretation so as to encompass all such modifications and similar structures.

What is claimed is:

1. An improved cooling module holder, comprising:
a main body disposed a cooling fan and a heat sink on two sides thereon respectively to form a cooling module and having a ventilation hole corresponding to said cooling fan and a plurality of still blades extending inwardly from an inner rim of said ventilation hole.

2. The improved cooling module holder of claim 1, wherein said plurality of still blades are in form of plate having an angle of tilt.

3. The improved cooling module holder of claim 1, wherein said plurality of still blades resemble a fan blade pattern of said cooling fan.

4. The improved cooling module holder of claim 1, wherein a plurality of inner sides of said plurality of still blades are connected with a fixing ring.

5. The improved cooling module holder of claim 1, wherein a plurality of feet extending from a periphery of said main body toward said side disposed said heat sink are assembled with said cooling module on a specified position atop a heating element.
